(19) United States
(12) Patent Application Publication
(10) Pub. No.: US 2004/0145042 A1
(43) Pub. Date: Jul. 29, 2004

(54) Semiconductor device

(76) Inventors: Sadayuki Morita, Higashiyamato (JP); Yoshikazu Saitou, Hamura (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/756,497

(22) Filed: Jan. 14, 2004

(30) Foreign Application Priority Data
Jan. 14, 2003 (JP) 2003-005235

(51) Int. Cl. H01L 23/48

(52) U.S. Cl. 257/692

(57) ABSTRACT

The present invention provides, in a memory which stacks a plurality of large-capacity SRAM chips or in a large-capacity SRAM chip which is mounted on a system LSI, the SRAM chips which can be easily stacked and facilitate bonding. Address pads which supply predetermined address signals to circuit blocks from the outside and data input/output pads which input/output data with respect to the circuit block are formed over a semiconductor chip. The data input/output pads are arranged along a first side of the semiconductor chip, the address pads are arranged along a second side which shares one of corners of the semiconductor chip with the first side, and the data input/output pads are not arranged on the second side. Due to such a constitution, by arranging the address pads on one side of the chip and the data input/output pads on another side of the chip in a concentrated manner, stacking and bonding of the chips are facilitated.

### BACKGROUND OF THE INVENTION

The present invention relates to a semiconductor device, and more particularly to a multi-chip package semiconductor device which mounts a plurality of semiconductor chips on one package. To be more specific, the present invention relates to a technique for stacking a plurality of memories such as SRAM (static random access memories) or the like on one package or laminating the memories in combination with a system LSI chip on one package.

Along with the sophistication and the increase of capacity of electronic equipment, the development of a multi-chip package (MCP) technique which realizes high-packing-density mounting by forming a plurality of semiconductor chips in one semiconductor package has been in progress. As specific methods on the technique for mounting a plurality of chips on one semiconductor package, there have been known a method which arranges a plurality of chips on one substrate in plane and a method which stacks a plurality of chips in a laminated manner. With respect to the latter stacked MCP technique, at the time of performing wire bonding of chip terminals and pads formed over four sides of the chip to be stacked, a width (an interval) is provided between the chips which are laminated in the height direction using spacers. Further, a technique which arranges pads on two neighboring sides of a chip and a plurality of these chips are stacked has been also disclosed (see Patent Literature 1 and Patent Literature 2, for example).

[Patent Literature 1]

Japanese Unexamined Patent Publication No. Hei4(1992)-199566 (FIG. 1)

[Patent Literature 2]

Japanese Unexamined Patent Publication No. 2001-196526 (FIG. 1)

### SUMMARY OF THE INVENTION

In the process for arriving at the present invention, inventors of the present invention et al. have found that in preparing a conventional memory which stacks a plurality of large-capacity SRAM chips, following points have to be taken into consideration to satisfy needs for the large memory capacity. That is, in the conventional SRAM chip, the pads on the chip are arranged on two opposing sides of the chip. Accordingly, in stacking the chips, it is necessary to ensure a width in the height direction using spacers or the like so as to ensure a height necessary for bonding. Accordingly, a package size is enlarged so that the number of chips to be stacked is limited.

Further, in case a large-capacity SRAM chip is added to a system LSI which mounts a CPU, a memory, a logic and the like on one chip, when the large-capacity SRAM is mounted on one chip together with the system LSI chip on which the logic, ROM and the like are mounted to enhance functions of the system LSI, since the size of the SRAM chip is large compared to other chips and hence, the chip size is increased. This leads to the increase of a package size and the lowering of a yield rate attributed to the SRAM chip. Further, the system LSI process basically adopts multi-layered wiring compared to the SRAM process and hence, a wiring layer formed over the SRAM becomes useless.

When the SRAM chip and the system LSI chip are prepared separately and both chips are stacked in place of the above-mentioned constitution, there arises a case that both chips cannot be stacked depending on the chip size and the arrangement position of the bonding pads of the conventional SRAM chip.

To solve such a drawback, as described in the above-mentioned patent literatures, the pads may be arranged on two neighboring sides, wherein the stacked chips are mounted in an obliquely displaced manner whereby the bonding can be performed easily.

However, in stacking the SRAM chips using the technique disclosed in the above-mentioned patent literatures, the inventors of the present invention have found that to facilitate stacking and bonding, it is necessary to take the arrangement positions of the address pads and data input/output pads into consideration. Further, to allow stacking of the SRAM to the existing SRAM package in view of the reduction of cost and the availability, it is necessary to take the pad positions of the SRAM chip into consideration. Further, also in stacking the SRAM chip and the system LSI chip together, it is necessary to take some consideration with respect to the arrangement of the pad positions for facilitating the stacking of the chips.

The present invention has been made in view of the above-mentioned drawbacks and it is an object of the present invention to provide a SRAM chip which enables easy stacking of a system LSI and a SRAM or easy stacking of SRAM chips.

The above-mentioned and other objects and novel features of the present invention will become apparent from the description of the specification and the attached drawings.

To briefly explain the summary of representative inventions among the inventions disclosed in this specification, they are as follows. That is, in a semiconductor device which forms a circuit block, a plurality of address pads for supplying predetermined address signals to the circuit block from the outside, and a plurality of data input/output pads for inputting or outputting data with respect to the circuit block over a semiconductor chip having four sides, the plurality of data input/output pads are arranged along the first side of the semiconductor chip, the address pads are arranged along the second side which shares one corner of the semiconductor chip together with the first side, and the data input/output pads are not arranged over the second side.

### BRIEF DESCRIPTION OF THE DRAWINGS

FIG. 1 is a top plan view of a semiconductor device according to a first embodiment of the present invention which mounts a plurality of SRAM chips on a TSOP (Thin Small Outline Package);

FIG. 2 is a bottom plan view of the semiconductor device according to the first embodiment of the present invention on which the plurality of SRAM chips are mounted on the TSOP;

FIG. 3 is a cross-sectional view of the semiconductor device according to the first embodiment of the present invention on which the plurality of SRAM chips are mounted on the TSOP;

FIG. 4 is a schematic view of the SRAM chip according to the first embodiment of the present invention;

FIG. 5 is a top plan view of a semiconductor device according to a second embodiment of the present invention which mounts a plurality of SRAM chips on a CSP (Chip Scale Package);

FIG. 6 is a schematic view of wiring of a board of the CSP according to the second embodiment of the present invention;

FIG. 7 is a schematic view of a semiconductor device according to a third embodiment of the present invention in which a SRAM chip and a system LSI chip which is smaller than the SRAM chip are stacked to each other;

FIG. 8 is a schematic view of a semiconductor device according to the third embodiment of the present invention in which a SRAM chip and a system LSI chip which is as large as the SRAM chip are stacked to each other;

FIG. 9 is a schematic view of a semiconductor device according to the third embodiment of the present invention in which a SRAM chip and a system LSI chip which is larger than the SRAM chip are stacked to each other; and

FIG. 10 is a schematic view of circuit blocks of the SRAM and the system LSI according to the third embodiment of the present invention.

### DESCRIPTION OF THE PREFERRED EMBODIMENTS

<Embodiment 1>

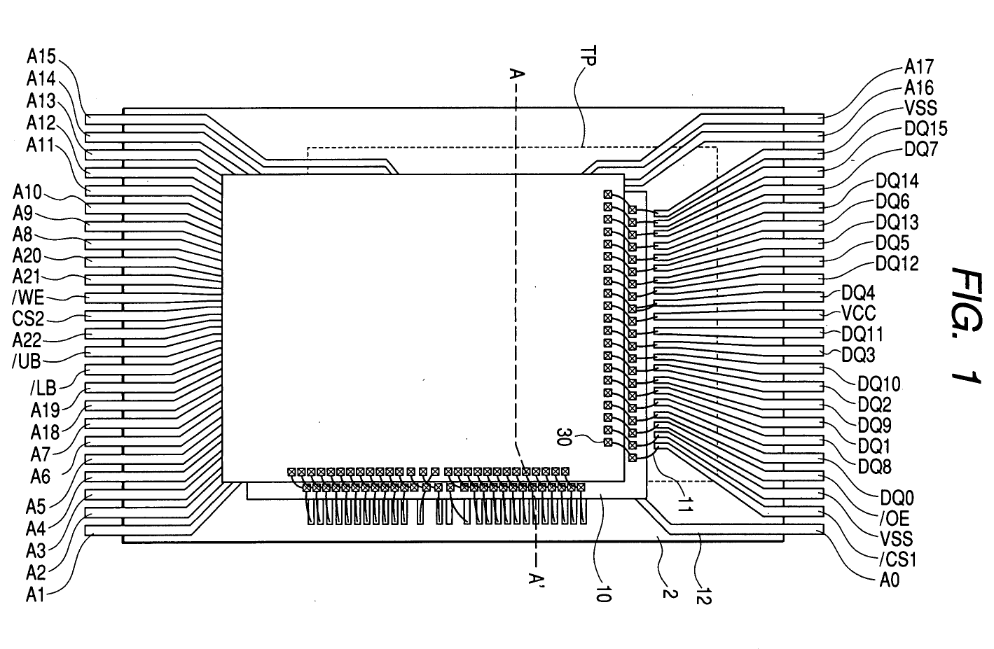

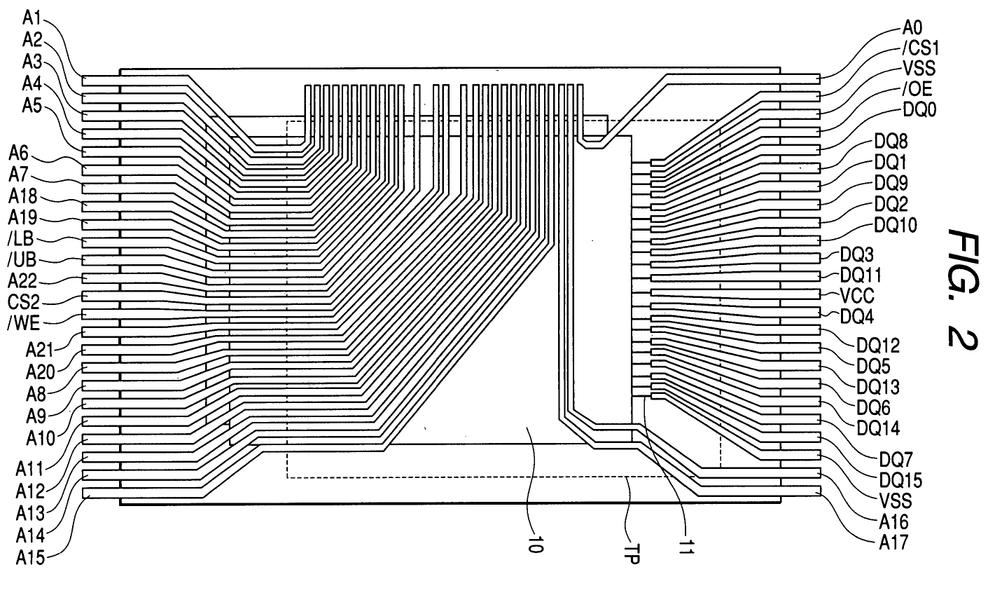

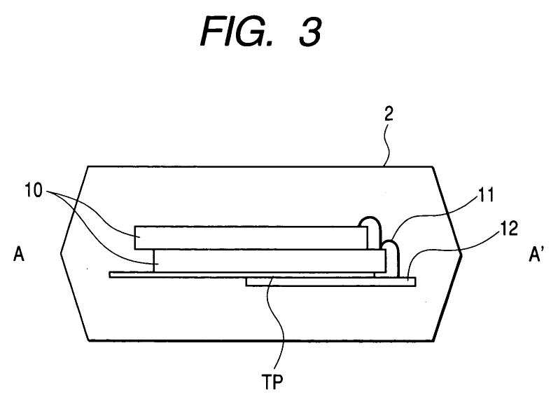

FIG. 1 is a top plan view of a semiconductor device 1 according to a first embodiment of the present invention which is mounted on a TSOP type package 2. In the drawings, with respect to semiconductor chips 10 of the semiconductor device, a plurality of the same kind of chips are stacked and are laminated such that the chips do not overlap other chips on which bonding pads described later are stacked. FIG. 2 is a bottom plan view of the semiconductor device 1 shown in FIG. 1. FIG. 3 is a schematic cross-sectional view showing a cross section of the semiconductor device 1 taken along a line A-A′ in FIG. 1.

In FIG. 1, a plurality of semiconductor chips 10 are stacked, bonding pads 30 which input/output external signals are arranged at two sides of the semiconductor chip which share one corner in common, and bonding pads are not arranged on sides which respectively face the above-mentioned two sides in an opposed manner respectively. Further, as described later, the bonding pads are comprised of address pads which are arranged at one side and a plurality of data input/output pads which are arranged at another side. The data input/output pads are not provided to the side on which the address pads are arranged, while the address pads are not formed over the side on which the data input/output pads are arranged. Further, with respect to the pads of respective chips which are stacked to each other, the pads of the chips are connected to each other using bonding wires 11 made of Au fine wires or the like, for example. Thereafter, the semiconductor device is sealed by resin made of epoxy-based resin or the like. The pads of the chip which is stacked on the lowermost surface are connected to terminals 12 of the semiconductor package using the bonding wires 11. The semiconductor chip is adhered to the terminals 12 using an adhesive tape TP, while the terminals 12 are connected with external terminals which enable the connection between the semiconductor chip and the outside. As the external terminals, address terminals A0 to A22, /UB, /LB, writing enable signals /WE, /OE, control signal terminals for operating a circuit block on the semiconductor chip such as chip select signals CS1, /CS1, CS2, /CS2 and the like, data input/output terminals DQ0 to DQ15, a VCC power source terminal for supplying electricity, a VSS ground potential terminal and the like are arranged.

In this embodiment, although it is not specifically limited, outer lead terminals which are connected with the bonding pads are arranged over two opposing sides (short sides) of the semiconductor package, wherein on one side, the outer leads are arranged in order of A1 to A7, A18, A19, /LB, /UB, A22, CS2, /WE, A21, A20 and A8 to A15. That is, the address terminals are arranged at both ends of the side and the control signal terminals are arranged at the center portion of the side. On the other hand, although it is not specifically limited, on another side, the external terminals are arranged in order of A0, /CS1, VSS, /OE, DQ0, DQ8, DQ1, DQ9, DQ2, DQ10, DQ3, DQ11, VCC, DQ4, DQ12, DQ5, DQ13, DQ6, DQ14, DQ7, DQ15, VSS, A16 and A17. That is, the address terminals, the control signal terminals and the ground potential terminal are arranged at ends of the side and the data input/output terminals and the power source terminals are arranged such that they are sandwiched by terminals arranged at both ends of the side. Further, the long sides of the package are arranged to be directed in the same direction as the direction of the long sides of the chip, wherein the side on which the data input/output pad is arranged is set parallel to the short sides of the package, while the side on which the address pad is arranged is set parallel to the long sides of the package.

In FIG. 2, out of the external terminal s which are arranged on two opposing sides of the semiconductor package, with respect to the terminals formed over the side in which the data input/output terminals are arranged, terminals except for the terminals A0, A16, A17, that is, the terminals other than the address terminals extend such that these terminals do not traverse the semiconductor chip. On the other hand, the terminals A0, A16 and A17 and the terminals formed over the side which faces the side over which the data input/output terminals are arranged in an opposed manner extend such that these terminals traverse the semiconductor chip.

FIG. 3 shows a cross-section of the TSOP type package 2 in which the terminal 12 is arranged on a chip mounting board of the package and a plurality of SRAM chips 10 of the present invention are stacked on the terminal 12. The pads of the stacked chip are connected to each other by means of the bonding wires 11, while the pads of the chip which constitutes a lowermost layer, that is, the chip which is mounted on a lead frame of the package while sandwiching an adhesive tape TP therebetween are connected to the terminals 12 by means of bonding wires.

With respect to the SRAM chips according to the present invention, the pads are arranged on two neighboring sides, wherein the address pads are formed over one side and the data input/output pads are formed over another side, whereby it is possible to mount a plurality of stacked SRAM chips without changing the pin arrangement of the existing SRAM package. Here, also with respect to the package to be mounted, by providing the address pads on one side thereof and the data input/output pads on another side so as to prevent the data input/output pads from being mounted on the side on which the address pads are arranged, it is possible to ensure the alignment between the package terminals and the chip pads. Further, in mounting the plurality of same SRAM chips, by mounting these chips in an obliquely displaced manner, it is unnecessary to provide spacers and hence, the reduction of cost can be achieved. Further, by eliminating the spacers, there exists no limitation with respect to the height direction of the stacked chips and hence, it is possible to stack the chips in a large number of stages.

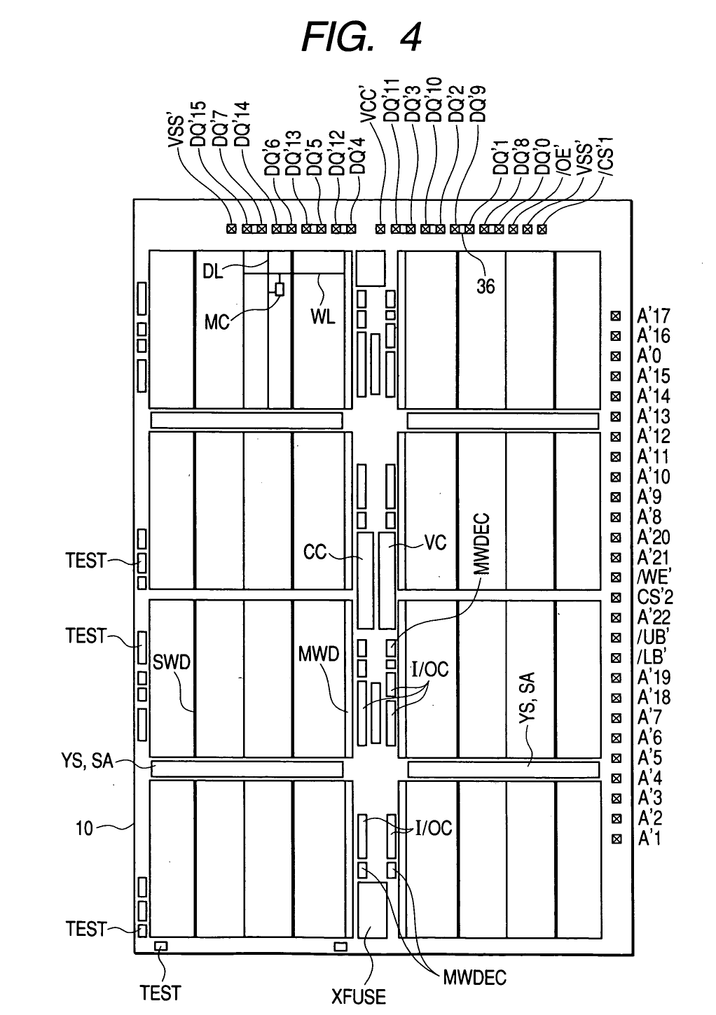

FIG. 4 is a schematic view showing a layout of the SRAM chips according to the present invention shown in FIG. 1. In the drawing, major components of a circuit block which constitutes the SRAM to which the present invention is applied are shown, wherein the components are formed over one semiconductor board made of single crystal silicon by a known manufacturing technique of semiconductor integrated circuit.

In the drawing, although it is not specifically limited, the semiconductor chip 10 is divided into a plurality of regions in the long-side direction as well as in the short-side direction, that is, in a crucifix form, and a plurality of memory arrays MA are arranged in each region. Around the memory arrays MA, peripheral circuits such as a main word driver MWD, a sensing amplifier SA, an X decoder XDEC, a Y decoder TDEC, an input circuit IC, an output circuit OC, a power-source-circuit column-system relief fuse circuit XFUSE, a row-oriented relief fuse circuit YFUSE are arranged. Outside the memory array MA and the peripheral circuit, pads TEST for a test and the bonding pads are arranged on sides of the semiconductor chip.

In the memory array MA, a plurality of word lines WL, a plurality of data lines DL, and memory cells MC which are arranged at intersections between the word lines and the data lines are arranged. In FIG. 4, such a constitution is represented by on word line, one data line and one memory cell. Although it is not limited, the memory cell MC is constituted of a flip-flop (having two p-channel type load MOS transistors and two n-channel type drive MOS transistors) to which inputs and outputs of a pair of CMOS inverters are alternately connected and two n-channel type transfer MOS transistors which selectively connect two memory nodes of the flip-flop to the data lines. To gate electrodes of the n-channel type MOS transistors, the word lines are connected. The word lines WL are connected to sub word drivers SWD to which a drive voltage of the word lines WL is supplied, while the sub word drivers SWD are connected to a main word driver MWD which selectively drives the sub word drivers SWD.

The bonding pads which are arranged at two neighboring sides of the semiconductor chip are constituted of address pads A′0 to A′22 which receive inputting of address signals, control signal pads which receive inputting of control signals, data input/output pads DQ′0 to DQ′15 which input/output data of memory cells, a power source pad VCC′ which supplies a power source voltage and a ground potential, a ground potential pad VSS′, a buffer (buffer circuit) 36 for inputting/outputting data and the like. To read out information from the memory cell MC of the SRAM or to write information in the memory cell MC of the SRAM, the address signals are inputted from the outside, row address signals and column address signals are generated and these signals are inputted to a row address buffer and a column address buffer not shown in the drawing. Then, an arbitrary memory cell in the inside of the memory array MA is selected through a row decoder and a column decoder. Then, the input/output data are inputted through an input/output buffer 36 at the time of performing the writing operation and are outputted through the sensing amplifier SA, an input/output bus and an input/output buffer 36 during the reading operation.

On the long side on which the address pads are arranged, the address pads and the control signal pads are arranged forming a row of pads and are arranged in the direction orthogonal to the word lines in view of the direction of flow of the signals. On the other hand, on the short side on which the data input/output pads are arranged, the power source pads, the ground potential pads and the like are arranged besides the data input/output pads and they are arranged in the direction perpendicular to the data lines. Further, at a corner which is sandwiched by the sides on which the pads are arranged, the pads are not arranged. In this case, it is preferable that the distance from the corner to the pad is not smaller than a sum of a minimum pitch of the pads and a layout width of the output buffer.

Further, over the semiconductor chip, testing pads for monitoring inner voltages are formed for taking out intermediate signals of an inner circuit block and for performing a defect analysis. These testing pads take out signals from the chip using a probe and are not bonded. In this embodiment, although the testing pads are provided to both of two sides opposing to the sides on which the address pads and the data input/output pads are arranged, the present invention is not limited to such a layout and the testing pads may be suitably arranged corresponding to the number of the testing pads.

In the SRAM according to the present invention, while the side on which the address pads are arranged and the data lines become parallel to each other, the side on which the data input/output pads are arranged and the word lines become parallel to each other. Accordingly, the pads are arranged along the flow of signals and hence, the wiring is prevented from becoming complicated. Further, since the address pads which outnumber the data input/output pads are arranged on the long side of the semiconductor chip, the pitch for arranging the pads is alleviated. Further, the pads for inputting the control signals are arranged at the center portion of the side on which the address pads are arranged, while the control signal pads and the ground potential pad are arranged at end portions of the side on which the data input/output pads are arranged and the power source pad is arranged on the center portion of the side on which the data input/output pads are arranged. Accordingly, it is possible to provide the pad arrangement which favorably conforms to the package of the above-mentioned TSOP type package whereby the terminals and the pads can be easily bonded to each other and, at the same time, it is possible to use the SRAM package. Further, with the provision of the pad arrangement inhibiting region, the pads can be arranged at the position away from the corner portion of the chip by a predetermined distance or more and hence, the bonding is facilitated.

Here, in this embodiment, although the address pads are formed over the long side of the semiconductor chip and the data input/output pads are formed over the short side, it may be possible that the address pads are arranged on the short side and the data input/output pads are arranged on the long side. Further, although the address pads usually outnumber the data input/output pads, when all of the address pads cannot be arranged on the long side or the short side, the address pads may be arranged on another side close to the side on which the data input/output pads are arranged. In this case, with respect to the side on which the data input/output pads are arranged, by adopting the layout in which the data input/output pads are arranged forming a group and, at the same time, the address pads are also arranged as a group as a neighboring group, the data input/output pads and the address pads can be easily mounted on the existing SRAM package. Further, in this embodiment, although the pad row is arranged in one row, the row of pads may be arranged in two rows or more. Further, the pad row may be arranged in a zigzag manner in two rows which is referred to as a staggered pattern.

<Embodiment 2>

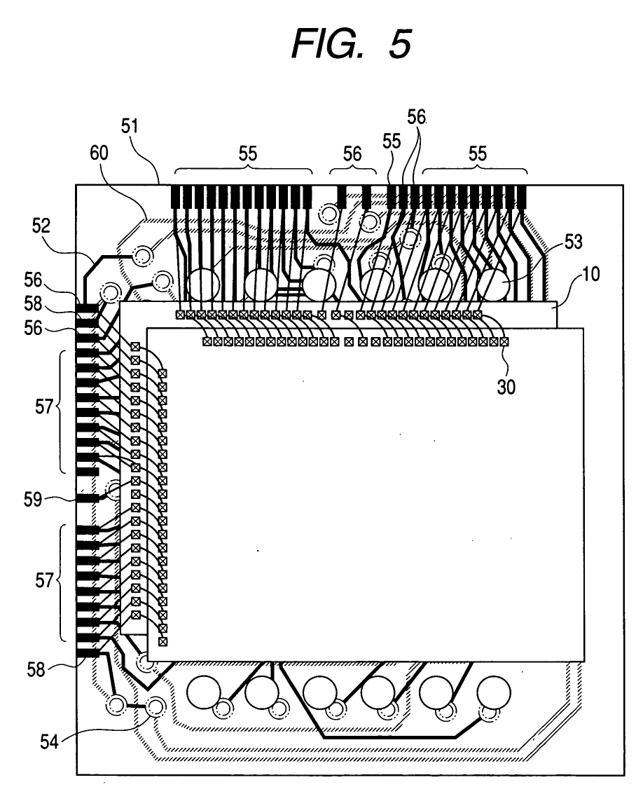

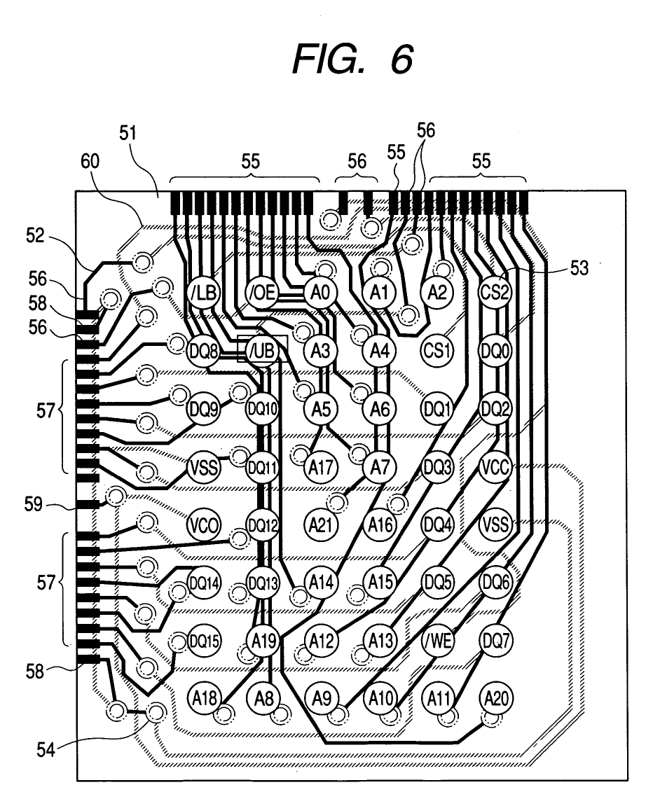

FIG. 5 is a top plan view of a semiconductor device 1 according to the second embodiment of the present invention, wherein a plurality of semiconductor chips 10 are stacked on a BGA (Ball Grid Array) type CSP (Chip Scale Package), while FIG. 6 is a printed circuit board of the semiconductor device 1 shown in FIG. 5. In FIG. 5, a plurality of SRAM chips having the substantially same constitution as the SRAM chips shown in FIG. 4 are stacked and pads of these chips are bonded to each other using bonding wires 11 formed of Au thin lines or the like, for example. The pads of the SRAM chip which is arranged as the lowermost layer of the package are bonded to inner terminals of the package using the wires 11 and are sealed by molding using resin or the like. The inner terminals of the package are constituted of address inner terminals 55, control signal inner terminals 56, data input/output signal terminals 57, a ground potential terminal 58, a power source terminal 59 and the like. Although there is no particular limitation, these inner terminals are arranged on two neighboring sides of the package. With respect to one of these sides, the address inner terminals 55 are arranged at both ends of the side and the control signal inner terminals 56 are arranged at a center portion of the side. On the other hand, with respect to another side, the control signal inner terminals 56 and the ground potential terminal 58 are arranged on end portions of the side and the data input/output terminals 57 and the power source terminal 59 are arranged in a state that these terminals are sandwiched by the control signal inner terminals 56 and the ground potential terminal 58.

FIG. 6 shows a state in which lines 52 formed over an upper portion of the board which extend from the inner terminals are connected to solder balls 53 through lines 60 formed over a lower portion of the board via through holes 54 or are connected directly to the solder balls 53 via the through holes 54. The balls 53 are arranged in a grid array, wherein respective balls function as address terminals, control signal terminals, data input/output terminals, a ground potential terminal and a power source terminal which correspond to the inner terminals.

In this embodiment, since the inner terminals are provided to two neighboring sides of the package, it is possible to have an advantageous effect that the chips according to the present invention can be easily bonded in addition to the advantageous effects which are explained in conjunction with the first embodiment. Further, by mounting the SRAM of the present invention on the BGA type CSP package, it is possible to mount the SRAM of large capacity to the miniaturized thin package.

<Embodiment 3>

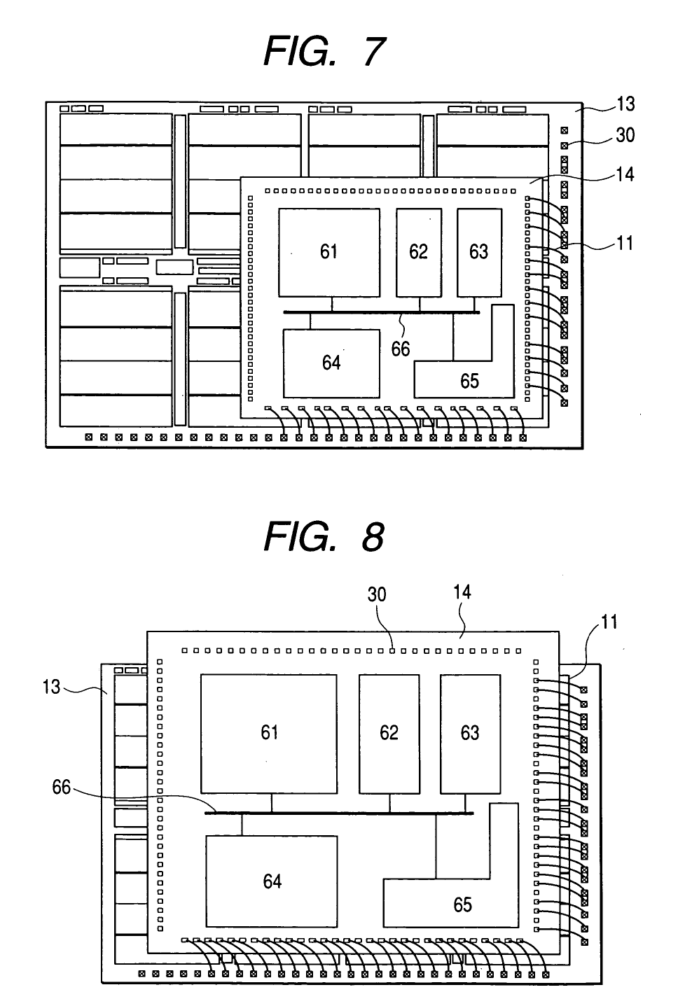

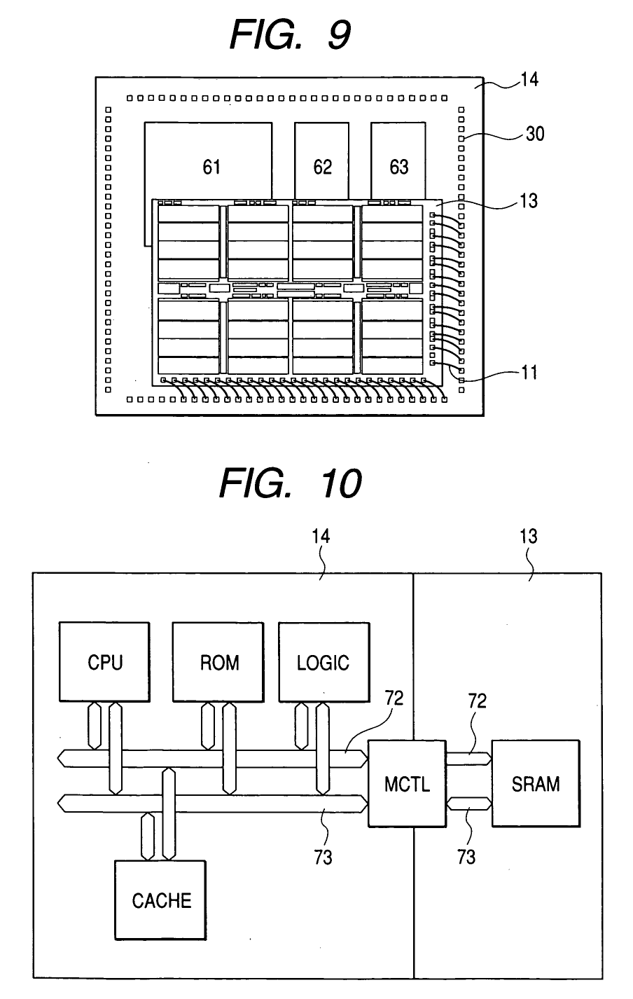

FIG. 7 to FIG. 10 show the third embodiment of the present invention in which the SRAM chips 13 shown in FIG. 3 and the system LSI chip 14 are stacked to each other. In this embodiment, FIG. 7 shows a case in which the SRAM chip is larger than the system LSI chip in size, FIG. 8 shows a case in which the SRAM chip is substantially equal to the system LSI chip in size, and FIG. 9 shows a case in which the SRAM chip is smaller than the system LSI chip. Although there is no particular limitation, the system LSI chip 14 is constituted of a plurality of circuit blocks such as a CPU 61, a memory 62, a logic 63, a cache RAM 64, an interface circuit 65 and the like, wherein these circuit blocks are connected to each other through an internal bus 66. On four sides of the system LSI chip, pads which are served for inputting and outputting signals with respect to the outside are arranged. Among the pads which are arranged on four sides of the system LSI chip, the pads formed over the side close to two sides on which the pads of the SRAM chip 13 are arranged are connected to the pads of the SRAM chip using bonding wires. To establish an interface between the SRAM chip and the system LSI chip stacked to each other, both of the SRAM chip and the system LSI chip are provided with pads and buffers for interface on two neighboring sides and both chips are stacked such that the corners which are respectively shared in common by two neighboring sides of both chips are aligned with each other.

FIG. 10 is a schematic view of the circuit blocks of the system LSI and the SRAM according to this embodiment. The address signals and data signal s which are outputted from CPU, ROM, LOGIC, CACHE are respectively inputted to an interface circuit MCTL through an internal address bus 72 and an internal data bus 73. The signals inputted to the interface circuit MCTL are inputted to the SRAM according to the present invention through the address bus 72 and the data bus 73. On the other hand, the data signal outputted from the SRAM are inputted to the interface circuit MCTL through the above-mentioned address bus 72 and data bus 73 and are respectively inputted to the ROM, the LOGIC and the like through the data bus. With respect to this circuit block diagram, operations related to the CPU, the ROM, the LOGIC and the CACHE are performed over the above-mentioned system LSI chip, while operations related to the SRAM are performed over the SRAM chip according to the present invention. The interface circuit MCTL is provided to both of the system LSI chip and the SRAM chip.

According to this embodiment, in the system LSI which mounts the large-capacity SRAM thereon, to facilitate stacking of the SRAM to the CPU, the LOGIC, the ROM and the like, the bonding pads of the large-capacity SRAM chip are arranged on two neighboring sides, wherein the address pads are arranged on one side and the data input/output pads are arranged on another side. In this manner, in the system LSI on which a plurality of circuit blocks such as the CPU, the LOGIC, the CACHE, the SRAM chip and the like are mounted, by designing the arrangement position of the pads of the SRAM chip which has the higher degree of freedom with respect to the arrangement position of the bonding pads than other chips, the SRAM chip can be easily stacked.

According to this embodiment, by stacking the SRAM chip to the system LSI chip by forming the address pads over one side out of two neighboring sides of the memory chip and forming the data input/output pads over another side, irrespective of the sizes of the logic chip and the memory chip, these chips can be easily stacked and bonded. Further, by arranging the pads and the buffers for establishing the interface on two neighboring sides of the memory chip and the logic chip and by arranging the bonding pads of the logic chip which are connected with the bonding pads of the memory chip on two sides which share one corner of the logic chip in common, bonding and stacking can be facilitated. Further, as mentioned previously, by providing the pad arrangement inhibiting region at the corner which is sandwiched by the sides over which the pads of the SRAM chip are formed, even when the system LSI chip is smaller than the SRAM chip as shown in FIG. 7, two chips can be easily bonded.

Although the invention made by the inventors of the present invention has been specifically explained in conjunction with the embodiments of the present invention, it is needless to say that the present invention is not limited to the above-mentioned embodiments and various modifications can be made without departing from the gist of the present invention.

For example, although the bonding pads are provided to two neighboring sides of the SRAM chip, wherein the address pads are formed over one side and the data input/output pads are formed over another side in this embodiment, for example, it may be possible to replace the SRAM chip with other memory chip such as DRAM, SSRAM or SDRAM. Further, it is also possible to replace the SRAM chip with a flash memory or the like which usually arranges the bonding pads on four sides of the chip. Further, in place of stacking the SRAMs to each other, it is also possible to stack the DRAMs to each other or to stack the SRAM and the DRAM to each other. Further, although the memory which is mounted on the system LSI is constituted of the SRAM in this embodiment, the memory which is mounted on the system LSI is not limited to the SRAM and other memory chip can be also used.

Further, with respect to the number of chips to be stacked, the system LSI and the SRAM are stacked in two stages or the SRAM are stacked in two stages in this embodiment. However, the semiconductor device which adopts stacking as a mounting method may adopt the multi-stage structure which exceeds the two-stage structure.

Further, although the stacked SRAM package has been explained by taking the TSOP type package and the BGA type package as examples, the SRAM of the present invention can be mounted on various types of packages including QFP (Quad Flat Package).

To briefly recapitulate the advantageous effects obtained by typical inventions among the inventions disclosed in this specification, they are as follows. That is, in the semiconductor device in which a plurality of chips are stacked, by arranging the bonding pads on two neighboring sides of the chip such that the address pads are arranged on one side and the data input/output pads are arranged on another side, stacking and bonding of the chips can be easily performed.

1. A semiconductor device comprising a semiconductor chip having four sides, including:
a circuit block;
a plurality of address pads for supplying predetermined address signals to the circuit block from the outside; and
a plurality of data input/output pads for inputting or outputting data with respect to the circuit block,
wherein the plurality of data input/output pads are arranged along the first side of the semiconductor chip,
wherein at least one of the plurality of address pads are arranged along a second side which shares in common one of corners of the semiconductor chip with the first side, and
wherein the plurality of address pads and the plurality of data input/output pads are not arranged in a third side which faces the first side in an opposed manner and a fourth side which faces the second side in an opposed manner.

2. A semiconductor device according to claim 1,
wherein pads for inputting or outputting external signals with respect to the semiconductor chip by bonding are not arranged in the third side or the fourth side, and
wherein testing pads of an internal circuit which are not bonded are arranged in the third side and the fourth side.

3. A semiconductor device according to claim 1,
wherein pads for supplying control signals and power source supply necessary for operating the circuit block are arranged in the first side, the second side or both of the first and second sides, and
wherein pads for control signals and power source supply necessary for operating the circuit block are not arranged in the third and fourth sides.

4. A semiconductor device according to claim 1,
wherein the plurality of data input/output pads are not arranged in the second side.

5. A semiconductor device according to claim 4,
wherein the plurality of address pads are not arranged in the first side.

6. A semiconductor device comprising a plurality of stacked chips including first and second chips,
wherein the first chip is a quadrangular chip and comprises a plurality of bonding pads including a plurality of first address pads and a plurality of data input/output pads,
wherein the plurality of data input/output pads are arranged in a first side of the quadrangular chip,
wherein the plurality of first address pads are arranged in a second side which shares in common one of corners of the quadrangular chip with the first side,
wherein the plurality of data input/output pads are not arranged in the second side, and
wherein pads for inputting and outputting external signals by bonding are not arranged in a third side which faces the first side in an opposed manner and in a fourth side which faces the second side in an opposed manner.

7. A semiconductor device according to claim 6,
wherein the first chip further includes a plurality of second address pads which are arranged in the first side, and
wherein the number of the plurality of second address pads is smaller than the number of plurality of data input/output pads.

8. A semiconductor device according to claim 7,
wherein the plurality of data input/output pads are arranged close to each other as a group in the first side and, at the same time, the plurality of second address pads are arranged close to each other as a group.

9. A semiconductor device according to claim 6,
wherein bonding pads for inputting address signals are not arranged in the first side.

10. A semiconductor device according to claim 9,
wherein the first chip includes a memory array including a plurality of memory cells which are provided at intersections between a plurality of word lines and a plurality of data lines, and
wherein the plurality of data lines are arranged in the direction parallel to the second side.

11. A semiconductor device according to claim 10,
wherein the first chip has a rectangular shape and
wherein the second side is a long side of the first chip.

12. A semiconductor device according to claim 11,
wherein the plurality of bonding pads further include control signal pads which input control signals to the first chip and a power source pad which supplies a predetermined potential to the first chip, and
wherein the control signal pads and the power source pad are arranged in the first and the second sides and are not arranged in the third and the forth side.

13. A semiconductor device according to claim 6,
wherein the semiconductor device further includes a package over which the plurality of chips are mounted,
wherein the package includes a plurality of outer lead terminals which are connected with the plurality of bonding pads, and
wherein the plurality of outer lead terminals are arranged in two opposing sides of the package.

14. A semiconductor device according to claim 13,
wherein the side in which the plurality of data input/output pads are arranged is parallel to the short-side direction of the package.

15. A semiconductor device according to claim 14,
wherein the plurality of outer lead terminals are arranged in the short sides of the package.

16. A semiconductor device according to claim 15,
wherein the plurality of outer lead terminals which are arranged in one of the short sides are respectively connected with the plurality of data input/output pads, and
wherein the plurality of outer lead terminals which are arranged in another side of the short sides are not connected with the plurality of data input/output pads.

17. A semiconductor device according to claim 6,
wherein the semiconductor device further includes a package having a board over which the plurality of chips are mounted,
wherein the board includes pads which are connected with the plurality of bonding pads of the first chip, and
wherein the pads arranged over the board are arranged in two neighboring sides of the package.

18. A semiconductor device according to claim 17,
wherein the plurality of data input/output pads are connected with a plurality of pads formed along a first side of the board, and
wherein the pads which are connected with the plurality of data input/output pads are not formed in another side different from the first side of the board.

19. A semiconductor device according to claim 6,
wherein the plurality of chips are respectively chips of same type, and
wherein the plurality of chips are stacked in a displaced manner such that the plurality of bonding pads which are respectively arranged in the first and the second sides are not superposed over another stacked chip.

20. A semiconductor device which stacks a plurality of chips including memory chips each of which has four sides and logic chips each of which has four sides,
wherein the memory chip is a quadrangular chip and includes a plurality of first bonding pads which include a plurality of first address pads and a plurality of data input/output pads,
wherein the plurality of data input/output pads are arranged in a first side of the memory chip,
wherein the plurality of first address pads are arranged in a second side which shares one of corners of the quadrangular chip in common with the first side,
wherein the plurality of the data input/output pads are not arranged in the second side,
wherein pads for inputting or outputting external signals by bonding are not arranged in a third side which faces the first side in an opposed manner and in a fourth side which faces the second side in an opposed manner,
wherein the logic chip is a quadrangular chip and has a plurality of second boding pads in four sides, and
wherein out of the plurality of second bonding pads which are arranged over the logic chip, the bonding pads which are connected to the memory chip are arranged in two sides which share one of corners of the logic chip in common.
